(19) United States
(12) Patent Application Publication
(10) Pub. No.: US 2005/0240845 A1
(43) Pub. Date: Oct. 27, 2005

(54) Reducing Number of Pins Required to Test Integrated Circuits

(75) Inventors: Arindam SAHA, Mumbai (IN); Shankaranarayana K DESHAMANGALA, Mangalore (IN); Hasanuzzaman K. SHEIKH, Kolkata (IN); Girish A. MADPUWAR, Chandrapur MS (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 10/709,238

(22) Filed: Apr. 23, 2004

(51) Int. Cl. G01R 31/28

(52) U.S. Cl. 714/726

(57) ABSTRACT

Number of pins required to test integrated circuits are reduced by scanning in a sequence of bits sequentially on a pin. The scanned bits are shifted into a shift register, and then loaded into a select register. The bit values in the select register represent the set of tests desired to be performed, and the desired tests can accordingly be performed within the integrated circuit. As bits representing the desired tests can be scanned using a small number of pins, the aggregate number of pins required for testing may be reduced.

### BACKGROUND OF INVENTION

1. Field of the Invention

The present invention relates to the testing of integrated circuits, and more specifically to a method and apparatus for reducing number of pins required to test integrated circuits.

2. Related Art

Integrated circuits are often tested to verify whether the circuits operate in a desired manner. For example, an integrated circuit may be tested to ensure that each component (within the integrated circuit) generates desired outputs and/or in a desired duration in response to a corresponding input combination.

Pins are often used to provide the inputs or receive outputs of integrated circuits while testing. In a typical scenario, a tester provides inputs on a set of pins and examines the corresponding outputs on another set of pins. Pins are also used by integrated circuits to communicate with external devices/components.

In general, it is desirable to minimize the number of pins provided on an integrated circuit (for reasons of cost, size and various other reasons, well known in the relevant arts). According to one prior approach, the same pins provided for functional (i.e., non-testing state) operation are also used for testing to minimize the aggregate pin requirement.

Even in such a case, it is desirable to minimize any additional pins not otherwise required for functional operation. Therefore, what is required is a method and apparatus to reduce number of pins required to test integrated circuits.

### BRIEF DESCRIPTION OF DRAWINGS

The present invention will be described with reference to the following accompanying drawings.

FIG. 1 is a block diagram illustrating the details of an example environment in which the present invention may be implemented.

FIG. 2 is a block diagram illustrating the manner in which various tests of interest may be specified in one prior embodiment.

FIG. 3 is a block diagram illustrating the details of a tests enabler block in an embodiment of the present invention.

FIG. 4 is a flow chart illustrating the manner in which the number of pins required to test an integrated circuit may be reduced according to an aspect of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

1. Overview

An integrated circuit provided according to an aspect of the present invention contains a pin on which bits forming a portion of a test code are scanned in sequentially. The test code represents the specific tests to be performed in parallel. As the bits are scanned sequentially, the number of pins required to specify the specific tests to be performed in parallel are reduced.

In one embodiment, the bits scanned via the pin are shifted in sequentially into a shift register. The bits in the shift register are then loaded into a select register, with the bit values in the select register specifying whether a corresponding test will be performed or not. Thus, while the tests are being performed using the bit values in the select register, the test code corresponding to the next set of tests are scanned into the shift register. Such scanning potentially allows new tests to be started while other tests are in progress. As a result, the aggregate time required to test an integrated circuit may be reduced as well.

Various aspects of the present invention are described below with reference to an example problem. Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well_known structures or operations are not shown in detail to avoid obscuring the invention.

2. Example Environment

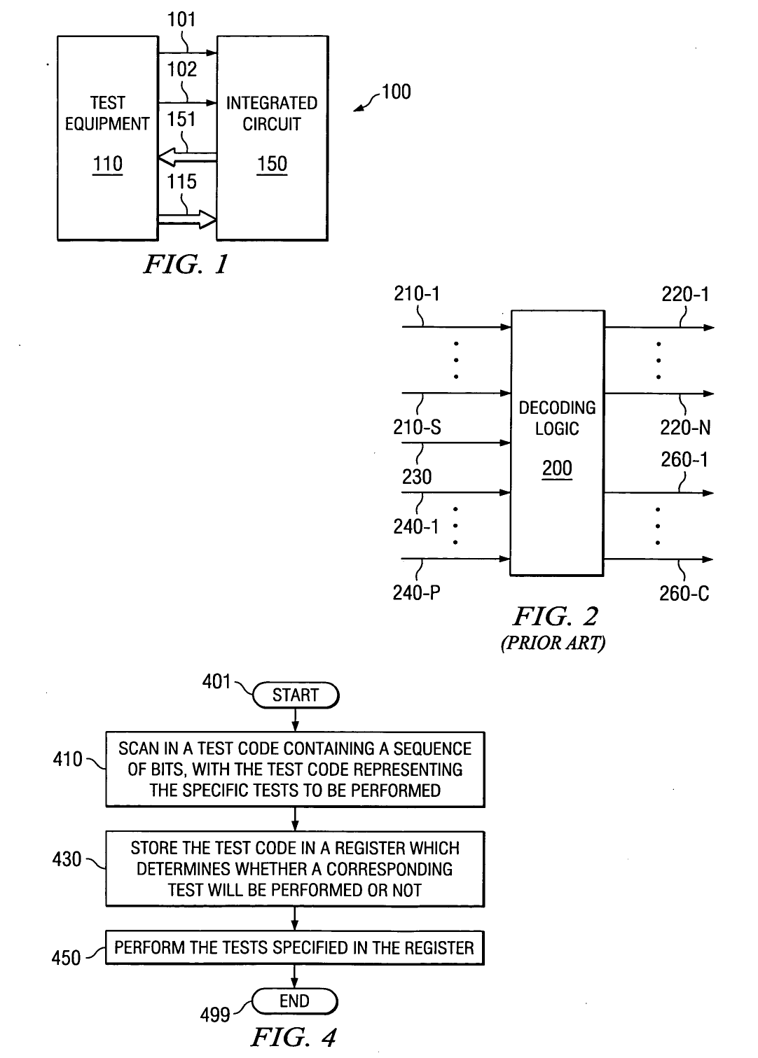

FIG. 1 is a block diagram illustrating an example environment in which the present invention can be implemented. Example environment 100 is shown containing test equipment 110 and integrated circuit 150. As described below in further detail, integrated circuit 150 can be tested using test equipment 110 according to various aspects of the present invention.

In general, design for testability (DFT) circuitry is included in the design of integrated circuits, which enables various tests to be run after manufacturing of the integrated circuits. A single test may generally be intended to perform a specific testing operation. Some of such tests include testing for stuck-at fault (if a signal is erroneously stuck at a specific logical value) and/or transition fault testing, logic built-in self test (BIST), memory BIST (to test the operation of any memory present), digital to analog converter/analog to digital converter (DAC/ADC) tests, phase locked loop (PLL)/clock test, etc.

Test equipment 110 sends a status signal on path 101 indicating whether integrated circuit 150 is to be operated in a test state or a functional state. For example, a logic 1 on path 101 indicates that IC 150 is to be operated in the test state, and a logic 0 indicates that IC 150 is to be operated in functional state. Test equipment 110 may send data on path 115 indicating various tests that are to be run by integrated circuit 150 and the input data (test vectors) to be used for the tests (when in the test state). Test equipment 110 may receive output (of tests) on path 151 in response to the data. The output on path 151 can be examined to verify proper operation of integrated circuit 150. Test equipment 110 sends signals on paths 101 and 115 at time points specified by clock signal 102.

Integrated circuit 150 receives on path 115 the data indicating the tests to be run and the input data for the tests, and performs the specified tests. An aspect of the present invention reduces the number of pins required for specifying the tests to be run. Such a feature will be clearer by first appreciating a prior approach, which may not include one or more features of the present invention. Accordingly, a prior approach is described below first.

3. Prior Testing Approach

FIG. 2 is a block diagram illustrating the details of a testing approach in a prior embodiment. The block diagram is shown containing decoding logic 200 along with select signals on pins 210-1 through 210-S, control signals on pins 240-1 through 240-P and status signal on pin 230. The operation of each component is described below in further detail.

Status signal 230 indicates whether the integrated circuit (containing the components of FIG. 2) is to operate in test state or functional state. Control signals 240-1 through 240-P provide various control signals required for test modes, for example, scan_mode signal used to indicate scan chain mode (in which input vectors may be scanned using a single pin in several successive clock cycles) assuming sequential scanning techniques such as ATPG are employed to scan the input vectors. Some of the control signals 240-1 through 240-P may be passed on paths 260-1 through 260-C, as needed for the specific tests.

Select signals 210-1 through 210-S contain a digital code, which represents in binary format the specific test modes to be performed. Each test mode may in turn be defined to include one or more tests than can be performed in parallel.

Decoding logic 200 decodes the S-bit number received on select signals 210-1 through 210-S into corresponding (2\hat{ }S) bits, wherein A represents a ‘power of mathematical operation. The corresponding (2\hat{ }S) signals are shown represented by 220-1 through 220-N (wherein N=2\hat{ }S). Each of the N-bits indicates whether a corresponding test mode is to be performed. Thus, further portion of an integrated circuit may receive the N-bits and perform the corresponding tests.

One potential problem with the prior approach is that more number of pins are required if number of test modes is increased. For example, number of test modes implemented equals ‘N’, then the number of pins required to provide select signals equals log₂N. In addition, extra pins are required to provide control signals 240-1 through 240-P. Thus, total number of pins required equals (log₂N+P). Accordingly, to increase the number of possible test modes (available in a testing environment), the number of pins may need to be increased, which is generally undesirable.

Another potential problem with the prior approach of FIG. 2 is that it may not be possible to provide a tester/user the ability to select any combination of tests (or a test mode, according to description above). In theory, assuming a total of T tests, the number of possible test modes may be given by the below equation: TTest modes=Σ^{T}C_{I} Equation (1) I=1 wherein C represents a ‘combination’ mathematical operation.

To extend the approach of FIG. 2 to provide a tester/ user the flexibility of selecting any of the test modes of Equation (1), would require a substantial number of pins (a large value of S in FIG. 2). It may be noted that all possible test modes may not be valid.

As a compromise, a designer may choose to provide only a subset of the large number of combinations of Equation (1), and thereby reduce the number of pins required accordingly. The small number of test modes may be chosen such that the tests that need to be performed in parallel (either for testing purpose or to minimize the total cost/ time of usage of testing equipment).

The absence of flexibility in selecting any desired combination of tests as a test mode may be undesirable for several reasons. For example, while testing, a user may recognize a specific test mode could reduce the tester time (and thus cost), but the specific test is not provided as a test mode due to the design choices made to reduce pin-count. Such high costs are generally not desirable. Various aspects of the present invention overcome some of such problems as described below in further detail.

4. Embodiment According to Various Aspects of the Invention

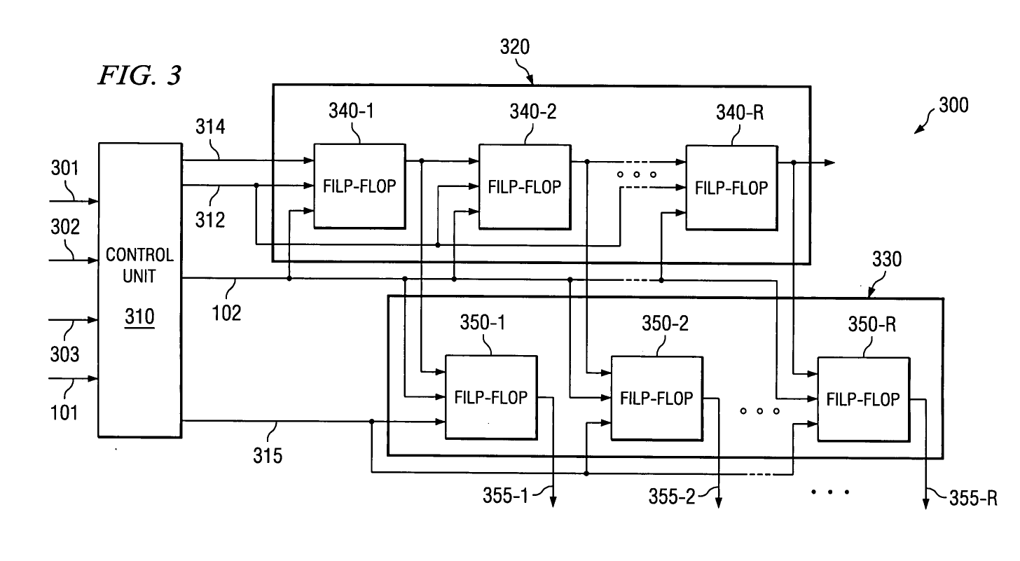

FIG. 3 is a block diagram illustrating the details of tests enabler block 300 in an embodiment implemented according to various aspects of the present invention. Tests enabler block 300 is described with reference to FIG. 1 for illustration. However, tests enabler block 300 may be used to reduce pins requirement of devices in other environments as well without departing from the scope and spirit of various aspects of the present invention. Tests enabler block 300 is shown containing control unit 310, shadow register 320 and select register 330. Each component is described in detail below.

Broadly, tests enabler block 300 may enable a user to run any desired tests (otherwise permitted by circuit design/operation) in parallel using only a fixed number of pins. Shadow register 320 stores as many number of bits as the number of tests for a design. The bits are stored by scanning in the bits sequentially into shadow register 320. Select register 330 loads the bits from shadow register 320 and each output of select register 330 enables the corresponding circuit portion in integrated circuit 150 to run the corresponding test. To run two or more tests concurrently, the bits in shadow register 320 corresponding to the tests are set and the corresponding outputs of select register 330 enable the circuit portions of integrated circuit 150. As a result, the number of pins required to run any number of tests concurrently can be small and fixed. Various pins required in an example embodiment are described below.

Shadow register 320 contains flip-flops 340-1 through 340-R, which are connected in sequence forming a shift register. Each flip-flop 340-1 through 340-R is shown receiving shift 312 and clock 102. Output of each flip-flop is shown connected to the input of next flip-flop and input of flip-flop 340-1 is shown receiving data_in 314. Shadow register 320 shifts in each bit in data_in 314 for every cycle of clock signal 102 when shift 312 is enabled. The number (R) of flip-flops in shadow register 320 may equal the number of tests to be run in integrated circuit 150 and the corresponding control signals (such as scan mode signal as described above) required to enable various tests.

Select register 330 (example storage element) may also contain as many number of flip-flops (350-1 through 350-R) as in shadow register 320. Each flip-flop 350-1 through 350-R stores the corresponding bit stored in the flip-flops of shadow register 320 when load 315 is enabled (load phase). For example, flip-flop 350-1 stores the bit present in flip-flop 340-1, flip-flop 350-2 stores the output from flip-flop 340-2, etc. The bits stored in flip-flops 350-1 through 350-R are provided as outputs on paths 355-1 through 355-R. As a result, the outputs on paths 355-1 through 355-R represent the tests to be run concurrently and the control signals correspond to the tests. For example, if output on paths 355-1 and 355-2 are 1, then the corresponding tests 1 and 2 are run concurrently.

Control unit 310 receives various input signals on a fixed number of pins, and generates intermediate signals. In an embodiment, the input signals include data_in, test phase control (TPC) 0, TPC1 and status signal, which are respectively received on pins 301, 302, 303 and 101. Paths 301, 302 and 303 may be contained in path 115 of FIG. 1. Status signal 101 indicates whether integrated circuit 150 is to be operated in test state or functional state. A sequence of bits representing a test code, which indicates various tests that are to be run by integrated circuit 150 in parallel, may be scanned in on path 301 in a shift phase (described below).

TPC0 302 and TPC1 303 together control the operation of test enabler block 300 in four phases corresponding to the four combination of bit values for TPC0 and TPC1.

When TPC0 302 and TPC1 303 are both at logic 0 (“freeze phase”), the tests which are presently being performed, are continued. The bits in shadow register 320 and select register 330 are unchanged in the freeze phase.

In a shift phase, when TPC0 302 and TPC1 303 are at logic 0 and logic 1 respectively, data_in 301 is scanned sequentially into shadow register 320. The corresponding sequence of bits (test code) may be provided by test equipment 110. The values in select register 330 are unchanged and the tests presently being performed are continued.

In a load phase, when TPC0 302 and TPC1 303 are at logic 1 and logic 0 respectively, data_in previously (in shift phase) scanned into shadow register 320, is loaded into select register 330. As noted above, the bits in select register 330 determine the specific tests performed in parallel.

In a self test phase, when both TPC0 302 and TPC1 303 are at logic 1, tests enabler block 300 itself is put in a scan chain for ATPG testing to test the correctness of tests enabler block 300. Such implementations may be performed in a known way.

Control unit 310 receives the sequence of bits (forming the test code) on data_in 301, and forwards the received bits on path 314 when the TPC bits indicate a shift phase. In addition, the shift signal 312 is enabled causing the bits to be shifted in (to support the scan operation). When the TPC bits indicate a load phase, control unit 310 enables load signal on path 315 causing the data in shadow register 320 to be loaded into select register 330.

It may be noted that while one set of tests are being performed, the test code corresponding to next set of tests may be scanned sequentially into shadow register 320 since the bits stored in select register 330 are changed only when load 315 is enabled. Even though, the implementation of shadow register 320 makes the next set of tests ready for execution before the present tests are completed execution, the scanning in of the bits into shadow register 320 consumes more clock cycle. In an alternative embodiment, to reduce the scanning time, multiple bits may be scanned through multiple (small number) pins.

In the above described embodiments, it may be noted that only four pins are required to run any number of tests. Since control signals (such as scan mode) may also be scanned in on path 301, extra pins to provide select signals and control signals as described with reference to prior approach of FIG. 2 may not be required. However, additional pins (or additional circuit logic) may be required to provide common signals such as scan_in (to provide test vectors), scan_out (to receive resulting output in response to test vectors) for ATPG testing, etc.

Thus, by operating tests enabler block 300 in the four phases, any combination of tests may be specified for parallel/concurrent execution using a small number of pins as further summarized below with reference to FIG. 4.

5. Method

FIG. 4 is a flow chart illustrating the manner in which the number of pins required to test an integrated circuit may be reduced according to an aspect of the present invention. The method is described with reference to FIGS. 1 and 3 for illustration. However, the method may be implemented in another environments as well. The method begins in step 401, in which control immediately passes to step 410.

In step 410, a test code containing a sequence of bits are scanned in sequentially on a pin, with the test code representing the specific tests to be performed. In the embodiments described above, the test code contains as many number of bits as the number of tests. The sequence of bits are scanned on pin data_in 301 of FIG. 3.

In step 430, the test code is stored in a register which determines whether a corresponding test will be performed or not. With reference to FIG. 3, the sequence of bits received on path 301 are shifted sequentially into shadow register 320. The bits stored in shadow register 320 are loaded into select register 330, the bit values on outputs of select register 330 determines whether the corresponding test will be performed or not.

In step 450, the tests specified in the register are performed based on the bit values. For example, if the bit value on output 355-1 equals logic 1 and output 355-1 represents test 1, then test 1 is performed. The method ends in step 499.

Thus, it may be noted that by sequentially scanning in a sequence of bits on a pin, the number of pins required to test an integrated circuit may be reduced. In addition, any combination (permitted by the design) of tests can be run in parallel by changing the bit values in the test code.

6. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

1. A method of testing an integrated circuit, said method comprising:
scanning in a plurality of bits sequentially on a pin, said plurality of bits forming a test code which indicates the specific ones of a plurality of tests to be performed; and
performing said specific ones of said plurality of tests in parallel.

2. The method of claim 1, wherein each of said plurality of bits indicates whether a corresponding one of said plurality of tests is to be performed.

3. The method of claim 2, further comprising:
shifting in said plurality of bits into a shift register; and
loading said plurality of bits from said shift register to a second register, wherein a bit value in each bit of said second register determines whether a corresponding one of said plurality of tests is to be performed.

4. The method of claim 3, wherein said shifting and said performing are performed in parallel.

5. The method of claim 4, wherein said scanning scans a plurality of control bits on said pin, said plurality of control bits representing control signals associated with said plurality of tests.

6. The method of claim 5, wherein said scanning scans some bits of said test code on a first pin and some other bits of said test code on a second pin, wherein said pin corresponds to one of said first pin and said second pin.

7. A tests enabler block reducing a number of pins required to test an integrated circuit, said tests enabler block being contained in said integrated circuit, said tests enabler block comprising:
a first pin receiving a plurality of bits sequentially, said plurality of bits forming a test code which indicates the specific ones of a plurality of tests to be performed to test said integrated circuit.

8. The tests enabler block of claim 7, wherein each of said plurality of bits indicates whether a corresponding one of said plurality of tests is to be performed.

9. The tests enabler block of claim 8, further comprising a first storage element storing said plurality of bits, wherein a bit value in each bit of said first storage element determines whether a corresponding one of said plurality of tests is to be performed.

10. The tests enabler block of claim 9, further comprises a shift register into which said plurality of bits are shifted in sequentially after being received by said first pin.

11. The tests enabler block of claim 10, wherein said first storage element comprises a first register, wherein said plurality of bits are loaded from said shift register to said first register.

12. The tests enabler block of claim 11, further comprises:
a second pin receiving a status signal indicating whether said integrated circuit is to be operated in a test state or a functional state;
a plurality of phase pins receiving a plurality of phase signals, wherein said plurality of phase signals operate said shift register in a shift phase in which said plurality of bits are scanned into said shift register, said plurality of phase signals operate said first register in a load phase in which said plurality of bits are loaded from said shift register to said first register.

13. The tests enabler block of claim 12, wherein a new plurality of bits are scanned sequentially into said shift register while said plurality of tests being performed, wherein said new plurality of bits indicate a new plurality of tests to be performed.

14. The tests enabler block of claim 13, wherein said first pin receives a plurality of control bits sequentially, said plurality of control bits representing control signals associated with said plurality of tests.

15. The tests enabler block of claim 14, wherein some bits of said test code are scanned in on a third pin and some other bits of said test code are scanned in on a fourth pin, wherein said first pin corresponds to one of said third pin and said fourth pin.
